(19) United States
(12) Patent Application Publication
(10) Pub. No.: US 2013/0344702 A1
(43) Pub. Date: Dec. 26, 2013

(54) METHOD OF ETCHING SILICON NITRIDE FILMS

(71) Applicant: Tetsuya Nishizuka, Sendai (JP)

(72) Inventor: Tetsuya Nishizuka, Sendai (JP)

(73) Assignee: TOKYO ELECTRON LIMITED, Tokyo (JP)

(21) Appl. No.: 14/002,477

(22) PCT Filed: Mar. 3, 2012
(86) PCT No.: PCT/US2012/027632

§ 371 Date: Sep. 11, 2013

Related U.S. Application Data
(60) Provisional application No. 61/449,560, filed on Mar. 4, 2011.

(51) Int. Cl. H01L 21/3065

(52) U.S. Cl. CPC H01L 21/3065
USPC 438/724

(57) ABSTRACT

A processing method is provided for plasma etching features in a silicon nitride (SiN) film covered by a mask pattern. The method includes providing a film stack on a substrate, the film stack containing a SiN film on the substrate and a mask pattern on the SiN film, transferring the mask pattern to the SiN film by exposing the film stack to a first plasma containing a carbon-fluorine-containing gas, O₂ gas, and optionally HBr gas, and exposing the film stack to a second plasma containing a carbon-fluorine-containing gas, O₂ gas, a silicon-fluorine-containing gas, and optionally HBr gas.

The present application claims priority to U.S. provisional application Ser. No. 61/449,560, filed on Mar. 4, 2011, the entire contents of which are herein incorporated by reference.

### FIELD OF THE INVENTION

1. Field of the Invention

The present invention relates to a method for fabricating a semiconductor device, and more particularly, to a plasma etching method of silicon nitride (SiN) films using a patterned mask.

2. Background of the Invention

Many semiconductor fabrication methods employ plasma to perform etching processes where material on a wafer is removed in specific areas to subsequently form the components/features of the devices (e.g., transistors, capacitors, conductive lines, vias, and the like) on the wafer. The fabrication methods use a mask pattern that is formed over areas of the wafer that are to be protected from the etching process.

During etching of deep features requiring long plasma exposure times, the mask pattern may be completely removed from the wafer surface and thereby leave the surface unprotected. Therefore, etching of deep features on a wafer can be limited by the etch selectivity between the material of the mask pattern and the material to be etched, where the higher the selectivity, the deeper the feature may be etched. Furthermore, etching of deep features generally requires straight feature sidewalls and high etch selectivity to material at the bottom of the features.

Silicon nitride (SiN) films are widely used in microfabrication processes as a dielectric and mask material. Semiconductor processing often involves etching features in a relatively thick layer of SiN film on a Si wafer substrate or on a relatively thin layer of silicon dioxide (SiO₂) supported upon a Si wafer substrate, where high selectivity of SiN etching over both Si and SiO₂ is strongly desired to reduce or prevent damage incurred by an underlying SiO₂ film or Si substrate.

There is a need for new methods for increasing the selectivity during etching of deep SiN features with straight sidewalls, such that a sufficient portion of the mask pattern remains to cover areas of the wafer to be protected until the etch process is complete and such that the underlying substrate materials are not etched or damaged. Further, lateral etch of the mask layer and SiN sidewalls can reduce the width of the etched SiN features below acceptable limits.

### SUMMARY OF THE INVENTION

Embodiments of the invention provide processing methods for plasma etching features in SiN films covered by a mask pattern. The processing methods provide deep SiN features with straight sidewalls and good etch selectivity to the mask pattern and underlying materials.

According to one embodiment of the invention, the method includes providing a film stack on a substrate, the film stack containing a silicon nitride (SiN) film on the substrate and a mask pattern on the SiN film, forming a first plasma from a first process gas containing a carbon-fluorine-containing gas, O₂ gas, and optionally HBr gas, and performing a main etch (ME) step by exposing the film stack to the first plasma. The method further includes forming a second plasma from a second process gas containing a carbon-fluorine-containing gas, O₂ gas, a silicon-fluorine-containing gas, and optionally HBr gas, and performing an over etch (OE) step by exposing the film stack to the second plasma. According to one embodiment, the method further includes applying a first pulsed RF bias power to the substrate holder during the exposure to the first plasma, and applying a second pulsed RF bias power to the substrate holder during the exposure to the second plasma, where the first pulsed RF bias power is greater than the second pulsed RF bias power applied to the substrate holder.

According to another embodiment of the invention, the method includes providing a film stack on a substrate, the film stack containing a silicon nitride (SiN) film on the substrate and a mask pattern on the SiN film, forming a first plasma from a first process gas containing a fluorocarbon gas, O₂ gas, and HBr gas, and performing a main etch (ME) step by exposing the film stack to the first plasma. The method further includes forming a second plasma from a second process gas containing a fluorocarbon gas, O₂ gas, HBr gas, and a silicon-fluorine-containing gas, and performing an over etch (OE) step by exposing the film stack to the second plasma. In one example, the first process gas contains CF₄ gas, HBr gas, O₂ gas, and Ar gas, and the second process gas contains CF₄ gas, HBr gas, O₂ gas, Ar gas, and SiF₄ gas.

According to yet another embodiment of the invention, the method includes providing a film stack on a substrate, the film stack containing a silicon nitride (SiN) film on the substrate and a mask pattern on the SiN film, forming a first plasma from a first process gas containing a hydrofluorocarbon gas and O₂ gas, and performing a main etch (ME) step by exposing the film stack to the first plasma. The method further includes forming a second plasma from a second process gas containing a hydrofluorocarbon gas, O₂ gas, and a silicon-fluorine-containing gas, and performing an over etch (OE) step by exposing the film stack to the second plasma. In one example, the first process gas contains CH₃F gas, O₂ gas, and Ar gas, and the second process gas contains CH₃F gas, O₂ gas, and SiF₄ gas.

### BRIEF DESCRIPTION OF THE DRAWINGS

FIGS. 1A-1C show transfer of a mask pattern through a SiN film on a substrate according to an embodiment of the invention;

FIG. 1D shows the effects of lateral etch during plasma etching of a film stack containing a mask pattern on a SiN film;

FIG. 2 schematically shows pulsing of RF bias power to a substrate holder supporting a substrate during plasma etching according to embodiments of the invention;

FIGS. 3A and 3B schematically show effects of pulsing RF bias power to a substrate holder supporting a substrate during plasma etching according to embodiments of the invention;

FIG. 4 is a schematic diagram of a plasma processing system containing a radial line slot antenna (RLSA) plasma source for SiN pattern etching according to one embodiment of the invention; and

FIG. 5 depicts a flow diagram of a method of transferring a mask pattern through a SiN film on a substrate according to an embodiment of the invention.

### DETAILED DESCRIPTION OF SEVERAL EMBODIMENTS

Embodiments of the invention are described with reference to the accompanying drawings, in which exemplary embodiments of the invention are shown. The ensuing description is not intended to limit the scope, applicability or configuration of the disclosure. Rather, the ensuing description of several exemplary embodiments will provide those skilled in the art with an enabling description for implementing exemplary embodiments of the invention. It should be noted that embodiments of the invention may be embodied in different forms without departing from the spirit and scope of the invention as set forth in the appended claims.

Embodiments of the invention are directed to a SiN plasma etching process that provides SiN etch features (e.g., trenches) with straight sidewall profiles and high etch selectivity of SiN to an overlying mask pattern and to a material at the bottom of the SiN etch features. In some embodiments, the SiN etch features are formed using a mask pattern containing SiO₂, SiON, or a combination thereof. In some embodiments, the material at the bottom of the SiN etch features contains SiO₂, Si, or a combination thereof. According to embodiments of the invention, a film stack is prepared on a substrate, where the film stack contains a silicon nitride (SiN) film on the substrate and a mask pattern on the SiN film. SiN etch features with straight sidewall profiles are achieved by forming a first plasma from a first process gas containing a carbon-fluorine-containing gas, O₂ gas, and optionally HBr gas, performing a main etch (ME) step by exposing the film stack to the first plasma, forming a second plasma from a second process gas containing a carbon-fluorine-containing gas, O₂ gas, a silicon-fluorine-containing gas, and optionally HBr gas, and performing an over etch (OE) step by exposing the film stack to the second plasma.

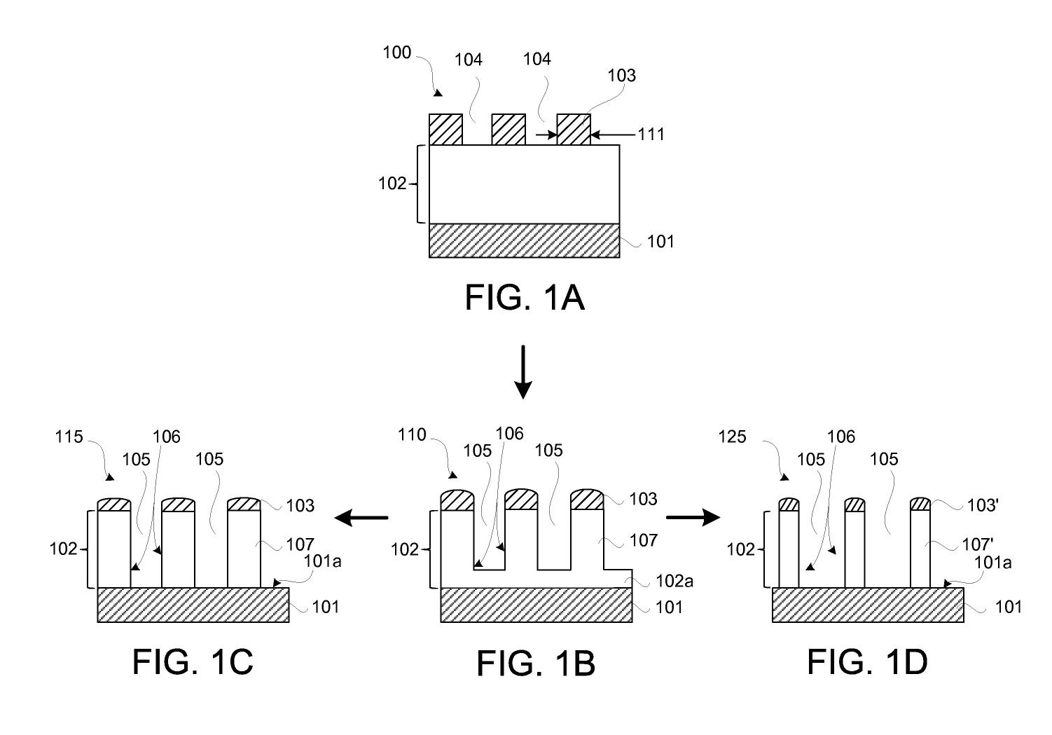

FIG. 1A shows a mask pattern formed on a SiN film on a substrate according to an embodiment of the invention. A film stack 100 contains a mask pattern 103 with mask openings 104 exposing a SiN film 102, and a substrate 101 under the SiN film 102. The mask pattern 103 can, for example, contain SiO₂, SiON, or a combination thereof. The mask pattern 103 can have a linewidth or critical dimension (CD) 111 and may be formed by conventional lithography and etching methods, for example using a photoresist (PR), and one or more layers selected from a silicon-containing antireflective coating (Si-ARC) and an organic dielectric layer (ODL). In some examples, the mask pattern 103 can have a CD 111 less than 100 nm, less than 50 nm, or less than 40 nm.

Although plasma etch processing may be particularly useful for etching multiple adjacent structures with fine features, as depicted in FIGS. 1A-1D, with demands on feature size and spacing become more stringent, limitations of plasma etch processes have become more apparent. One common limitation of plasma etching is with respect to the fabrication of an integrated circuit (IC) with variable spacing between various semiconductor structures on the same substrate. For example, the etch rate may exhibit a dependence on pattern density, a phenomenon referred to as “micro-loading”. At very small dimensions and particularly in high aspect ratio regimes, the etch rate of a material that has been patterned with a high density (i.e., smaller spacings between features) may be slower than the etch rate of the same materials patterned with a low density (i.e., larger spacings between features). Thus, an over-etching (OE) step may be required to fully etch all of the various structures on the same substrate, i.e., the areas that are first to completely etch continue to be exposed to the etch process while areas that have not completely etched undergo completion of the etch process. In some cases, the OE step may have detrimental impact on the resultant semiconductor structures if the OE step does not show good selectivity to the underlying materials and lateral etch of the features is not prevented or minimized. The high etch selectivity of the SiN film relative to a substrate and a mask pattern, significantly reduces the micro-loading effect when plasma etching a SiN film covered by mask pattern.

According to embodiments of the invention, the film stack 100 is plasma etched to form SiN etch features 105 (e.g., trenches) with straight sidewalls 106 and high etch selectivity of the SiN film 102 to the mask pattern 103 and a material at the bottom of the SiN etch features 105. FIG. 1B schematically shows transfer of the mask pattern 103 into the SiN film 102 in a high etch rate in a main etch (ME) step, thereby forming SiN pattern 107 and SiN etch features 105. After the ME step, partially patterned film stack 110 contains an unetched portion 102a of the SiN film 102. According to embodiments of the invention, the ME step utilizes a first process gas containing a carbon-fluorine-containing gas, O₂ gas, and optionally HBr gas. The hydrofluoro-carbon gas can contain or consist of CHF₃, CH₂F₂, or CH₃F, or a combination thereof. The carbon-fluorine-containing gas can contain or consist of CF₄. In some examples, during the ME step, the process chamber pressure may be between about 30 mTorr and about 200 mTorr, or between about 50 mTorr and about 150 mTorr, for example 70 mTorr.

According to one embodiment of the invention, the ME step may be performed using a first pulsed RF bias power that is applied to a substrate holder supporting the substrate 101 that contains the film stack 100. The use of the first pulsed RF bias power can aid in providing straight SiN sidewalls 106 in the SiN etch features 105 and providing high etch selectivity of the SiN film 102 relative to the mask pattern 103.

The ME step is followed by an over-etch (OE) step, characterized by an etch rate that is lower than the etch rate for the ME step, that utilizes a second process gas containing a carbon-fluorine-containing gas, O₂ gas, a silicon-fluorine-containing gas, and optionally HBr gas. The carbon-fluorine-containing gas can contain a fluorocarbon gas, a hydrofluorocarbon gas, or both a fluorocarbon gas and a hydrofluorocarbon gas. The hydrofluorocarbon gas can contain or consist of CHF₃, CH₂F₂, or CH₃F, or a combination thereof. The fluorocarbon gas can contain or consist of CF₄. The silicon-fluorine-containing gas can include SiF₄, SiHF₃, SiH₂F₂, or SiH₃F, or a combination thereof. According to some embodiments of the invention, the first and second process gases may include the same carbon-fluorine-containing gas but this is not required as the first and second process gases may include a different carbon-fluorine-containing gas. Similarly, the first and second process gases may include the same silicon-fluorine-containing gas but this is not required as the first and second process gases may include a different silicon-fluorine-containing gas.

In one example, an Ar/CF₄/O₂/HBr process gas may be used during the ME step and an Ar/CF₄/O₂/HBr/SiF₄ process gas may be used during the OE step. The inventors have realized that when CF₄ gas is utilized, HBr gas may be added to provide hydrogen (H) in the plasma environment that is beneficial to the etching process. In contrast, in another example, Ar/CH₃F/O₂ process gas may be used during the ME step and an Ar/CH₃F/O₂/SiF₄ process gas may be used during the OE step. In this example, the CH₃F provides H in the plasma environment, and HBr may not be needed. This also applies to other hydrofluorocarbon gases. However, in some examples, HBr may be combined with Ar/CH₃F/O₂ or Ar/CH₃F/CF₄/O₂ in the ME step and combined with Ar/CH₃F/O₂/SiF₄ or Ar/CH₃F/CF₄/O₂/SiF₄ in the OE step.

In some examples, the process chamber pressure may be between about 10 mTorr and about 200 mTorr during the OE step, or between about 30 mTorr and about 100 mT. The OE step may further utilize a second pulsed RF bias power to provide required etch selectivity of SiN film 102 to the mask pattern 103 and to the material of the substrate 101 at the bottom of the SiN etch features 105. According to some embodiments of the invention, the second pulsed RF bias power in the OE step can be lower than the first pulsed RF bias power in the ME step. The OE step may be performed for a time period that removes the unetched portion 102a of the SiN film 102 and an additional time period in order to ensure complete removal over the entire substrate of the unetched portion 102a of the SiN film 102 in the SiN etch features 105 while stopping on the surface 101a of the substrate 101. FIG. 1C schematically shows a fully patterned film stack 115 that contains SiN etch features 105 that extend through the entire SiN film 102 and stop on the surface 101a following the OE step. According to some embodiments, the SiN pattern 107 can have aspect ratios (height/width) between 1 and 5, or between 2 and 4.

As described above, in order to improve etch selectivity of the SiN film 102 to the mask pattern 103, the ME step, the OE step, or both the ME step and the OE step, may be performed by optionally pulsing the RF bias power applied to the substrate holder supporting the substrate 101. Improved etch selectivity of the SiN film 102 relative to the mask pattern 103 observed by pulsing the RF bias power is believed to be due to mask pattern protection during the OFF periods of the pulsing of the RF bias power.

During the ME step, it is believed that Si from the SiN film 102 being etched forms SiF byproducts and thereafter forms SiOF species that deposit on the film stack 110, including on the mask pattern 103 and on the SiN sidewalls 106. The deposited SiOF species protect the mask pattern 103 and the SiN sidewalls 106 against lateral etching. However, near or at the completion of the pattern transfer through the SiN film 102, less Si from SiN is available for formation of SiF byproducts and SiOF species. This leads to reduced protection of the mask pattern 103 and the SiN sidewalls 106 and results in increased lateral etching of the mask pattern 103 and the SiN sidewalls 106. As a result, as schematically shown in FIG. 1D, unacceptable reduction in CD is often observed in the film stack 125 containing reduced width SiN etch features 107′ and mask pattern 103′.

Embodiments of the invention address the problem of reduced amount of Si that is available from the SiN film 102 near or at the completion of the pattern transfer through the SiN film 102 by adding Si to the process gas in the form of a silicon-fluorine-containing gas in the OE step. This Si addition increases the formation of SiOF species in the plasma and provides better protection against lateral etching of the mask pattern 103 and the SiN sidewalls 106. As a result, the reduction in CD is prevented or minimized. According to some embodiments of the invention, a silicon-fluorine-containing gas may also be added to the ME step, however, this addition is usually not needed due to the normally high supply of Si for mask and sidewall protection during the SiN etch.

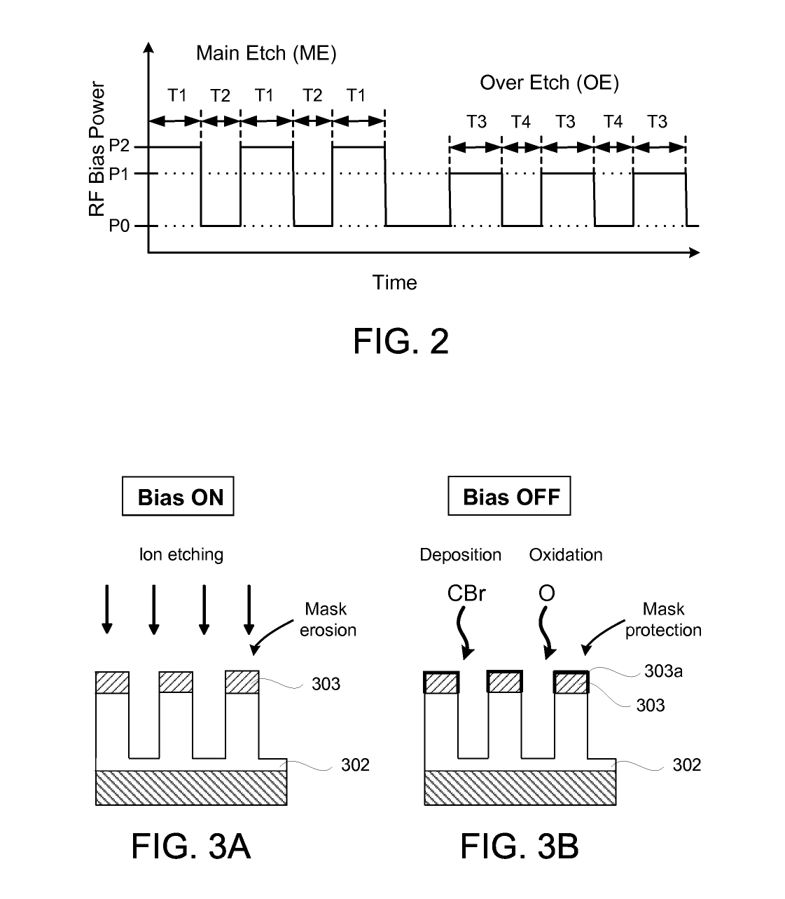

FIG. 2 schematically shows pulsing of RF bias power to a substrate holder supporting a substrate during plasma etching according to embodiments of the invention. The RF bias power applied to the substrate holder supporting the substrate during the ME step is maintained at a RF bias power P2 for a time period T1 (ON period), and thereafter, the RF bias power is maintained at a RF bias power P0 for a time period T2 (low bias power or OFF period), where the RF bias power P2 is greater than the RF bias power P0. According to some embodiments of the invention, the RF bias power P2 can be 100 W or greater, for example 110 W, 120 W, 130 W, 140 W, 150 W, 160 W, or greater. The RF power P0 can be 0 W or greater than 0 W, for example 10 W, 20 W, 30 W, 40 W, 50 W, or greater. According to some embodiments of the invention, the time period T1 can be greater than the time period T2. In other words, the duty cycle (T1/(T1+T2)) can be greater than 0.5 (50%), for example greater than 0.6 (60%), greater than 0.7 (70%), greater than 0.8 (80%), or even greater than 0.9 (90%). In other embodiments, the time period T2 can be equal to or greater than the time period T1. The pulsing frequency of the RF bias power P2 can be greater than 1 Hz, for example 2 Hz, 4 Hz, 6 Hz, 8 Hz, 10 Hz, 20 Hz, 30 Hz, 50 Hz, or greater. FIG. 2 only shows three pulse cycles of the pulsed RF bias power during the ME step but those skilled in the art will readily realize that a typical ME step will contain a large number of pulses. For example, for a ME step of 400 seconds using a pulse frequency of 10 Hz, contains 4,000 pulses of the pulsed RF bias power.

Still referring to FIG. 2, the RF bias power applied to the substrate holder supporting the substrate during the OE step is maintained at a RF bias power P1 for a time period T3 (ON period), and thereafter, the RF bias power is maintained at a RF bias power P0 for a time period T4 (low bias power or OFF period), where the RF bias power P1 is greater than the RF bias power P0. According to some embodiments of the invention, the RF bias power P1 can be less than the RF bias power P2, and can be less than 100 W, for example 90 W, 80 W, 70 W, 60 W, 40 W, 30 W, or even lower. The RF power P0 can be 0 W or greater than 0 W, for example 10 W, 20 W, 30 W, 40 W, 50 W, or greater. According to some embodiments of the invention, the time period T3 can be greater than the time period T4. In other words, the duty cycle (T3/(T3+T4)) can be greater than 0.5 (50%), for example greater than 0.6 (60%), greater than 0.7 (70%), greater than 0.8 (80%), or even greater than 0.9 (90%). In some examples, the duty cycle used in the OE step can be lower than the duty cycle used in the ME step. The pulsing frequency of the RF bias power P1 can be greater than 1 Hz, for example 2 Hz, 4 Hz, 6 Hz, 8 Hz, 10 Hz, 20 Hz, 30 Hz, 50 Hz, or greater. FIG. 2 only shows three pulse cycles of the pulsed RF bias power during the OE step but those skilled in the art will readily realize that a typical OE step may contain a large number of pulses.

Further, the plasma generation power supplied from the external microwave generator can be greater during the ME step than during the OE step, and therefore the plasma density may be greater in the process chamber during the ME step than during the OE step. For example, a plasma generation microwave power applied during the ME step can be between 2000 W and 3000 W, for example 3000 W, and a plasma generation microwave power applied during the OE step can be between 1000 W and 2000 W, for example 1800 W. In one example, the plasma generation microwave power applied during the ME step can be between 2000 W and 3000 W, and the RF bias power can be 100 W or greater. In one example, the plasma generation microwave power applied during the OE step can be between 1000 W and 2000 W, and the RF bias power can be less than 100 W. In some examples, the process chamber pressure may be higher during the ME step than during the OE step. For example, the process chamber pressure can be between about 30 mTorr and about 200 mT during the ME step and between about 10 mTorr and about 150 mT during the OE step. Etching times for the ME step depend on the thickness of the SiN film. In some examples, the etching times for the ME step can be between 1 minute and 10 minutes and etching times for the OE step can be between 10 seconds and 2 minutes.

Tables I and II show exemplary plasma etching conditions for ME and OE steps according to embodiments of the invention.

TABLE I
Exemplary plasma etching conditions for ME and OE steps.
The ME step uses an Ar/CF₄/O₂/HBr process gas
and the OE step uses Ar/CF₄/O₂/HBr/SiF₄ process gas.
The Power Top/Bot refers to RLSA microwave power (Top) and un-
pulsed RF bias power (Bot) applied to a substrate holder supporting
the substrate.

| | | Power | | | | | |
|---|---|---|---|---|---|---|---|
| | P | Top/Bot | Ar | CF₄ | O₂ | HBr | SiF₄ |
| Step | (mTorr) | (W/W) | (sccm) | (sccm) | (sccm) | (sccm) | (sccm) |
| ME | 70 | 3000/ | 200 | 100 | 50 | 1000 | 0 |
| | | 150 | | | | | |
| OE | 100 | 1500/ | 107 | 50 | 125 | 450 | 5-20 |
| | | 80 | | | | | |

TABLE II
Exemplary plasma etching conditions for the ME step and the OE
step. The ME step uses an Ar/CH₃F/O₂ process gas and the OE
step uses an Ar/CH₃F/O₂/SiF₄ process gas.

| | | Power | | | | |
|---|---|---|---|---|---|---|
| | P | Top/Bot | Ar | CH₃F | O₂ | SiF₄ |
| Step | (mTorr) | (W/W) | (sccm) | (sccm) | (sccm) | (sccm) |
| ME | 70 | 3000/ | 200 | 100 | 50 | 0 |
| | | 150 | | | | |
| OE | 100 | 100 | 1000 | 20 | 13 | 5-20 |

According to one embodiment, the method of processing a substrate includes providing a film stack on a substrate, the film stack containing a silicon nitride (SiN) film on the substrate and a mask pattern on the SiN film, forming a first plasma from a first process gas containing a carbon-fluorine-containing gas and O₂ gas, and performing a main etch (ME) step by exposing the film stack to the first plasma. The method further includes forming a second plasma from a second process gas containing a carbon-fluorine-containing gas, O₂ gas, a silicon-fluorine-containing gas, and performing an over etch (OE) step by exposing the film stack to the second plasma.

According to another embodiment, the method of processing a substrate includes providing a film stack on a substrate, the film stack containing a silicon nitride (SiN) film on the substrate and a mask pattern on the SiN film, forming a first plasma from a first process gas containing a fluorocarbon gas, O₂ gas, and HBr gas, and performing a main etch (ME) step by exposing the film stack to the first plasma. The method further includes forming a second plasma from a second process gas containing a fluorocarbon gas, O₂ gas, HBr gas, and a silicon-fluorine-containing gas; and performing an over etch (OE) step by exposing the film stack to the second plasma. In one example, the first process gas contains CF₄ gas, HBr gas, O₂ gas, and Ar gas, and the second process gas contains CF₄ gas, HBr gas, O₂ gas, Ar gas, and SiF₄ gas.

According to yet another embodiment, the method of processing a substrate includes providing a film stack on a substrate, the film stack containing a silicon nitride (SiN) film on the substrate and a mask pattern on the SiN film, forming a first plasma from a first process gas containing a hydrofluorocarbon gas and O₂ gas, and performing a main etch (ME) step by exposing the film stack to the first plasma. The method further includes forming a second plasma from a second process gas containing a hydrofluorocarbon gas, O₂ gas, and a silicon-fluorine-containing gas, and performing an over etch (OE) step by exposing the film stack to the second plasma. In one example, the first process gas contains CH₃F gas, O₂ gas, and Ar gas, and the second process gas contains CH₃F gas, O₂ gas, and SiF₄ gas.

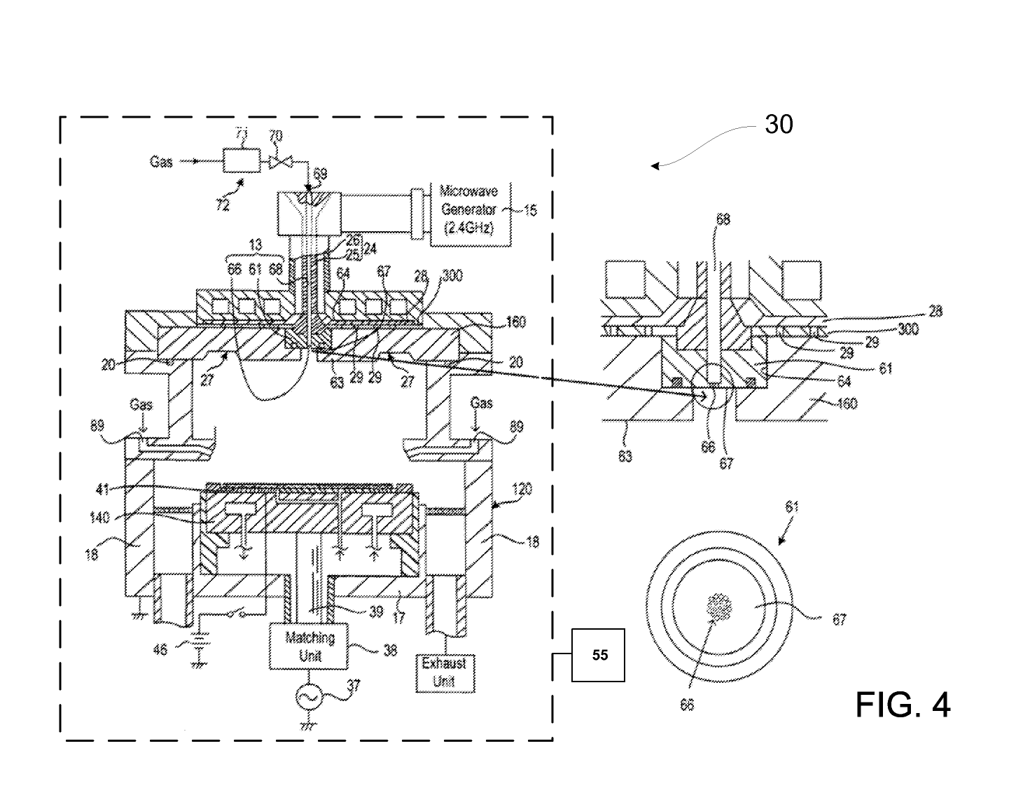

FIGS. 3A and 3B schematically show effects of pulsing RF bias power to a substrate during plasma etching according to embodiments of the invention. FIG. 3A schematically shows the effects of applying RF bias power to a substrate during transfer of the mask pattern 303 into a SiN film 302, where ions in the plasma are strongly accelerated towards the substrate and cause ion etching of the SiN film 302 and plasma erosion of the mask pattern 303. FIG. 3B schematically shows the effects of not applying RF bias power to the substrate, where ions in the plasma are not strongly accelerated towards the substrate and the plasma process proceeds by formation of a protection layer 303a on the mask pattern 303 by deposition and oxidation by exposure of the mask pattern 303 to neutral radicals (e.g., CBr and O). The protection layer 303a formed by the pulsing of the RF bias power protects the mask pattern 303 during a subsequent RF bias ON period, thereby increasing the etch selectivity of the SiN film 302 relative to the mask pattern 303.

FIG. 4 is a schematic diagram of a plasma processing system containing a radial line slot antenna (RLSA) plasma source for SiN pattern etching according to one embodiment of the invention. The plasma processing system 30 includes a process chamber 120, a radial line slot plate 300, a substrate holder 140 adapted to support a substrate to be processed (e.g., a 300 mm Si wafer), and a dielectric window 160. The process chamber 120 includes a bottom portion 17 located below the substrate holder 140 and cylindrical sidewall 18 that extends upwards from the circumference of the bottom portion 17. An upper portion of the process chamber 120 is open-ended. The dielectric window 160 is positioned opposite the substrate holder 140 and is sealed to the upper side of the process chamber 120 via O-rings 20. The plasma processing system 30 further includes a controller 55 that is configured to control the processing conditions and overall operation of the plasma processing system 30.

An external microwave generator 15 provides microwave power of a predetermined frequency, e.g., 2.45 GHz, to the radial line slot plate 300 via a coaxial waveguide 24 and a slow-wave plate 28. The external microwave generator 15 can be configured for providing microwave power between about 1000 W and 3000 W. The coaxial waveguide 24 may include a central conductor 25 and a circumferential conductor 26. The microwave power is then transmitted to the dielectric window 160 through a plurality of slots 29 provided on the radial line slot plate 300. The microwave from the external microwave generator 15 creates an electric field just below the dielectric window 160, which in turn causes excitation of a plasma gas within the process chamber 120. A concave part 27, provided on an inner side of the dielectric window 160, enables an effective plasma generation inside the process chamber 120.

An external high-frequency power supply source 37 is electrically connected to the substrate holder 140 via a matching unit 38 and an electric power supply pole 39. The high-frequency power supply source 37 generates an RF bias power of a predetermined frequency, e.g., 13.56 MHz, for controlling energy of ions that are drawn to a substrate. The matching unit 38 matches an impedance of the RF power supply source to an impedance of the load, e.g., the process chamber 120. According to embodiments of the invention, the microwave power provided by the external microwave generator 15 is utilized for generating plasma from a process gas in the process chamber 120 and the external high-frequency power supply source 37 is independently controlled from the external microwave generator 15 for accelerating ions in the plasma towards the substrate. An electrostatic chuck 41 is provided on an upper surface of the substrate holder 140 for holding the substrate by an electrostatic absorption power, via a DC power supply source 46.

The substrate holder 140 is adapted to receive RF bias power (signal) from the high-frequency power supply source 37 such that the substrate holder 140 serves as a biasing element with respect to the RF bias power to accelerating ionized gases towards the substrate during the etching process. The high-frequency power supply source 37 is configured to optionally provide pulsing of the RF bias power as schematically shown in FIG. 2 and the pulsing frequency can be greater than 1 Hz, for example 2 Hz, 4 Hz, 6 Hz, 8 Hz, 10 Hz, 20 Hz, 30 Hz, 50 Hz, or greater.

It is noted that one skilled in the art will appreciate that the power levels of the high-frequency power supply source 37 are related to the size of the substrate being processed. For example, a 300 mm Si wafer requires greater power consumption than a 200 mm wafer during processing.

The plasma processing system 30 further includes a process gas supply part 13. An enlarged view of the process gas supply part 13 is also shown in FIG. 4. As shown in this figure, the process gas supply part 13 may include a base injector 61 located at a recessed position, inside the dielectric window 160, compared to a lower surface 63 of the dielectric window 160. The process gas supply part 13 further includes a base holder 64 which extends through a portion of the thickness of the dielectric window 160 to hold the base injector 61. A plan view of the base injector 61 is also shown in FIG. 4. As shown in this figure, a plurality of supply holes 66 are provided on a flat wall surface 67 which is positioned opposite to the substrate holder 140. The plurality of supply holes 66 are positioned radially at a center of the flat wall surface 67.

The process gas supply part 13 further includes a gas duct 68. As shown in FIG. 4, the gas duct 68 extends through a central conductor 25 from the coaxial waveguide 24, the radial line slot plate 300, and the dielectric window 160, to reach the plurality of supply holes 66. A gas supply system 72 is connected to a gas entrance hole 69 formed at an upper end of the central conductor 25. The gas supply system 72 may include an on-off valve 70 and a flow rate controller 71, e.g., a mass flow controller. Further, the process gas may be supplied into the process chamber 120 by two or more gas ducts 89 provided on the cylindrical sidewall 18. The elemental composition of the process gas supplied into the process chamber 120 by the two or more gas ducts 89 may be the same as that of the process gas supplied into the process chamber 120 by the gas duct 68. According to some embodiments, the elemental composition of the process gas supplied into the process chamber 120 by the two or more gas ducts 89 may be independently controlled and may be different than the process gas supplied into the process chamber 120 by the gas duct 68. For some etch processes, the process chamber pressure may be controlled between about 10 mTorr and about 1000 mTorr.

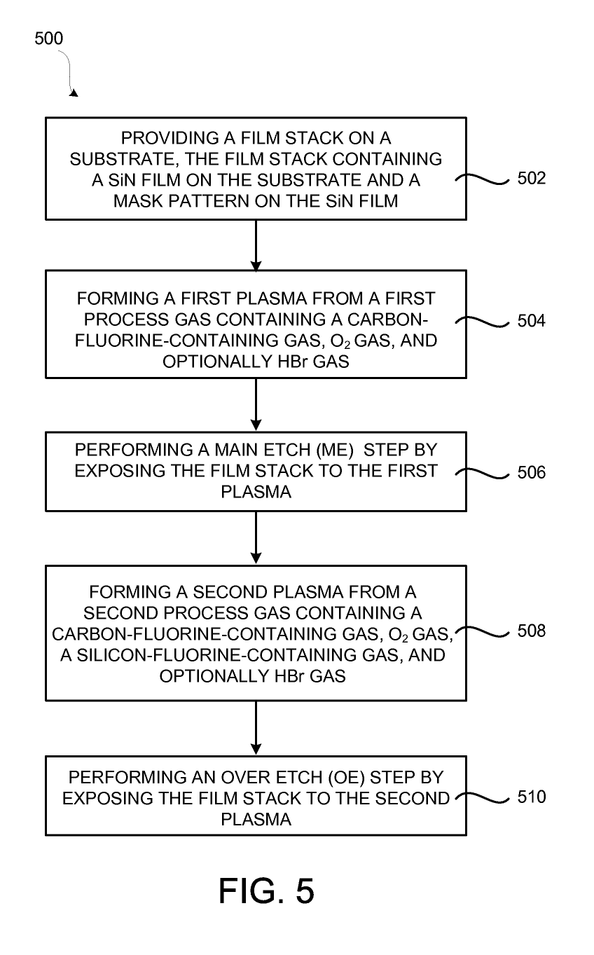

FIG. 5 depicts a flow diagram of a method of transferring a mask pattern through a SiN film on a substrate according to an embodiment of the invention. The flow diagram 500 includes, in 502, providing a film stack on a substrate, the film stack containing a SiN film on the substrate and a mask pattern on the SiN film. In some embodiments, the mask pattern can contain SiO₂, SiON, or a combination thereof, and the substrate can contain SiO₂, Si, or a combination thereof.

In 504, a first plasma is formed from a first process gas containing a carbon-fluorine-containing gas, O₂ gas, and optionally HBr gas. The carbon-fluorine-containing gas can contain a fluorocarbon gas, a hydrofluorocarbon gas, or both a fluorocarbon gas and a hydrofluorocarbon gas. In one example, the fluorocarbon gas contains or consists of CF₄. In some examples, the hydrofluorocarbon gas contains or consists of CHF₃, CH₂F₂, or CH₃F, or a combination thereof. The first process gas can further contain Ar gas or He gas. According to one embodiment, the first plasma may be formed by exciting the process gas by a microwave plasma source including a radial line slot antenna (RLSA).

In 506, a ME step is performed by exposing the film stack to the first plasma. The exposure to the first plasma transfers the mask pattern to the SiN film. According to some embodiments, continuous or pulsed RF bias power may be applied to a substrate holder supporting the substrate in the ME step.

In 508, a second plasma is formed from a second process gas containing a carbon-fluorine-containing gas, O₂ gas, a silicon-fluorine-containing gas, and optionally HBr gas. The carbon-fluorine-containing gas can contain a fluorocarbon gas, a hydrofluorocarbon gas, or both a fluorocarbon gas and a hydrofluorocarbon gas. In one example, the fluorocarbon gas contains or consists of CF₄. In some examples, the hydrofluorocarbon gas contains or consists of CHF₃, CH₂F₂, or CH₃F, or a combination thereof. The silicon-fluorine-containing gas can include SiF₄, SiHF₃, SiH₂F₂, or SiH₃F, or a combination thereof. The second process gas can further contain Ar gas or He gas.

In 510, an OE step is performed by exposing the films stack to the second plasma. According to some embodiments, continuous or pulsed RF bias power may be applied to a substrate holder supporting the substrate in the OE step.

According to some embodiments of the invention, the first and second process gases may include the same hydrofluorocarbon gas but this is not required as the first and second process gases may include the different a hydrofluorocarbon gas. Similarly, the first and second process gases may include the same silicon-fluorine-containing gas but this is not required as the first and second process gases may include a different silicon-fluorine-containing gas. According to one embodiment, the second plasma may be formed by exciting the process gas by a microwave plasma source including a radial line slot antenna (RLSA).

According to one embodiment, the transferring of the mask pattern through the SiN film includes etching through less than an entire thickness of SiN film in a main etch (ME) step, and thereafter, etching through a remaining thickness of the SiN film and stopping on the substrate in an over etch (OE) step. In one example, the transferring includes applying a first pulsed RF bias power to the substrate during the ME step, and applying a second pulsed RF bias power to the substrate during the OE step. According to one embodiment of the invention, the first pulsed RF bias power can be greater than the second pulsed RF bias power.

According to one embodiment, the transferring of the mask pattern through the SiN film includes etching through less than an entire thickness of SiN film in a main etch (ME) step using the first plasma, and thereafter, etching through a remaining thickness of the SiN film and stopping on the substrate in an over etch (OE) step using the second plasma. In one example, the transferring includes applying a first pulsed RF bias power to the substrate during the ME step, and applying a second pulsed RF bias power to the substrate during the OE step. According to one embodiment of the invention, the first pulsed RF bias power can be greater than the second pulsed RF bias power. According to some embodiments, the RF bias power may be continuous during the transferring of the mask pattern through the SiN film.

A plurality of embodiments providing processing methods for plasma etching features in SiN films covered by a mask pattern have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for processing a substrate, comprising:
providing a film stack on a substrate, the film stack containing a silicon nitride (SiN) film on the substrate and a mask pattern on the SiN film;
forming a first plasma from a first process gas containing a carbon-fluorine-containing gas and O₂ gas;
performing a main etch (ME) step by exposing the film stack to the first plasma;
forming a second plasma from a second process gas containing a carbon-fluorine-containing gas, O₂ gas, and a silicon-fluorine-containing gas; and
performing an over etch (OE) step by exposing the film stack to the second plasma.

2. The method of claim 1, wherein the ME step transfers the mask pattern to the SiN film by etching through less than an entire thickness of the SiN film, and thereafter, etching through a remaining thickness of the SiN film and stopping on the substrate in the OE step.

3. The method of claim 1, wherein the carbon-fluorine-containing gas comprises a fluorocarbon gas, a hydrofluorocarbon gas, or both a fluorocarbon gas and a hydrofluorocarbon gas.

4. The method of claim 3, wherein the first process gas, the second process gas, or both the first and second process gases further contain HBr gas.

5. The method of claim 3, wherein the hydrofluorocarbon gas contains or consists of CHF₃, CH₂F₂, or CH₃F, or a combination thereof.

6. The method of claim 3, wherein the fluorocarbon gas contains or consists of CF₄.

7. The method of claim 1, wherein the silicon-fluorine-containing gas contains SiF₄, SiHF₃, SiH₂F₂, or SiH₃F, or a combination thereof.

8. The method of claim 1, wherein the first process gas contains CH₃F gas, CF₄ gas, O₂ gas, Ar gas, and HBr gas, and the second process gas contains CH₃F gas, CF₄ gas, O₂ gas, HBr gas, Ar gas, and SiF₄ gas.

9. The method of claim 1, further comprising
applying RF bias power to a substrate holder supporting the substrate.

10. The method of claim 1, further comprising
applying pulsed RF bias power to a substrate holder supporting the substrate.

11. The method of claim 10, further comprising:
applying a first pulsed RF bias power to the substrate holder during the ME step; and
applying a second pulsed RF bias power to the substrate holder during the OE step.

12. The method of claim 11, wherein the first pulsed RF bias power is greater than the second pulsed RF bias power applied to the substrate holder.

13. The method of claim 1, wherein forming the first and second plasmas includes exciting the first and second process gases by a microwave plasma source including a radial line slot antenna (RLSA).

14. The method of claim 1, wherein the mask pattern comprises a SiON film, a SiO₂ film, or a combination thereof.

15. The method of claim 1, wherein the substrate comprises a Si film, a SiO₂ film, or a combination thereof.

16. The method of claim 1, wherein the first and second process gases further include Argon (Ar) gas or Helium (He) gas.

17. A method for processing a substrate, comprising:
providing a film stack on a substrate, the film stack containing a silicon nitride (SiN) film on the substrate and a mask pattern on the SiN film;
forming a first plasma from a first process gas containing a fluorocarbon gas, O₂ gas, and HBr gas;
performing a main etch (ME) step by exposing the film stack to the first plasma;
forming a second plasma from a second process gas containing a fluorocarbon gas, O₂ gas, HBr gas, and a silicon-fluorine-containing gas; and
performing an over etch (OE) step by exposing the film stack to the second plasma.

18. The method of claim 17, wherein the first process gas contains CF₄ gas, HBr gas, O₂ gas, and Ar gas, and the second process gas contains CF₄ gas, HBr gas, O₂ gas, Ar gas, and SiF₄ gas.

19. A method for processing a substrate, comprising:
providing a film stack on a substrate, the film stack containing a silicon nitride (SiN) film on the substrate and a mask pattern on the SiN film;
forming a first plasma from a first process gas containing a hydrofluorocarbon gas and O₂ gas;
performing a main etch (ME) step by exposing the film stack to the first plasma;
forming a second plasma from a second process gas containing a hydrofluorocarbon gas, O₂ gas, and a silicon-fluorine-containing gas; and
performing an over etch (OE) step by exposing the film stack to the second plasma.

20. The method of claim 19, wherein the first process gas contains CH₃F gas, O₂ gas, and Ar gas, and the second process gas contains CH₃F gas, O₂ gas, and SiF₄ gas.
